(19) United States
(12) Patent Application Publication
(10) Pub. No.: US 2025/0289951 A1
(43) Pub. Date: Sep. 18, 2025

(54) RESIN COMPOSITION FOR MOLDING AND ELECTRONIC COMPONENT DEVICE

(71) Applicant: RESONAC CORPORATION, Tokyo (JP)

(72) Inventors: Masashi YAMAURA, Minato-ku, Tokyo (JP); Ayumi NAKAYAMA, Minato-ku, Tokyo (JP); Tomoki HIRAI, Minato-ku, Tokyo (JP); Arisa YAMAUCHI, Minato-ku, Tokyo (JP); Mika TANAKA, Minato-ku, Tokyo (JP); Yuta SUKEGAWA, Minato-ku, Tokyo (JP)

(73) Assignee: RESONAC CORPORATION, Tokyo (JP)

(21) Appl. No.: 18/861,586

(22) PCT Filed: Jun. 9, 2023
(86) PCT No.: PCT/JP2023/021623

§ 371 Date: Oct. 30, 2024

(30) Foreign Application Priority Data
Jun. 10, 2022 (JP) 2022-094677

(51) Int. Cl. C08L 63/00; C08G 59/24; C08G 59/62; C08K 3/22; C08K 5/5397; H01Q 1/22

(52) U.S. Cl. CPC C08L 63/00; C08G 59/245; C08G 59/621; C08G 59/623; C08K 3/22; C08K 5/5397; H01Q 1/2283; C08K 2003/2237; C08L 2203/206

(57) ABSTRACT

This resin composition for molding contains: an epoxy resin; a curing agent containing an active ester compound and a phenol curing agent; and an inorganic filler containing calcium titanate particles.

### TECHNICAL FIELD

The present disclosure relates to a resin composition for molding and an electronic component device.

### BACKGROUND ART

In recent years, with the demand for higher functionality and miniaturization of electronic devices, the high-density integration and high-density mounting of electronic components have been progressing. As a result, semiconductor packages used in these electronic devices are becoming increasingly smaller compared to conventional ones. Furthermore, the radio waves used for communication in electronic devices are also becoming higher in frequency.

From the perspective of miniaturization of semiconductor packages and adaptation to high frequencies, high dielectric constant epoxy resin compositions for sealing semiconductor elements have been proposed (for example, see Patent Documents 1 to 3).

For example, Patent Documents 4 and 5 disclose thermosetting resin compositions including active ester resins as curing agents for epoxy resins, which are said to be capable of suppressing the dielectric loss tangent of the cured product to a low level.

### CITATION LIST

### Patent Document

Patent Document 1: Japanese Patent Application Laid-Open (JP-A) No. 2015-036410.
Patent Document 2: Japanese Patent Application Laid-Open (JP-A) No. 2017-057268.
Patent Document 3: Japanese Patent Application Laid-Open (JP-A) No. 2018-141052.
Patent Document 4: Japanese Patent Application Laid-Open (JP-A) No. 2012-246367.
Patent Document 5: Japanese Patent Application Laid-Open (JP-A) No. 2014-114352.

### SUMMARY

### Technical Problem

As a material for sealing electronic components such as semiconductor elements, for example, a resin composition for molding including epoxy resin, curing agent, and inorganic filler may be mentioned. In the case of using a material with a high dielectric loss tangent as the aforementioned resin composition for molding, transmission loss is likely to convert the transmission signal into heat, easily leading to decreased communication efficiency. Here, the amount of transmission loss generated when radio waves emitted for communication are converted to heat in a dielectric is expressed as the product of frequency, the square root of relative permittivity, and dielectric loss tangent. The transmission signal becomes more easily converted to heat in proportion to the frequency. Particularly in recent years, radio waves used for communication have been shifting to higher frequencies to accommodate the increase in channel numbers associated with the diversification of information. From the perspective of reducing transmission loss, there is a demand for a resin composition for molding capable of molding cured products with low dielectric loss tangent.

Further, in the case of using a resin composition for molding in the production of semiconductor packages including electronic components such as semiconductor elements, the resin composition for molding needs to meet the process applicability in the package production process. For example, in response to forming a redistribution layer after sealing electronic components with the resin composition for molding during semiconductor package production, an alkaline solution may be used. However, resin compositions for sealing using active ester compounds as curing agents have room for improvement in chemical resistance to alkaline solutions.

The present disclosure aims to provide a resin composition for molding capable of molding cured products with excellent chemical resistance and low dielectric loss tangent, and an electronic component device using the same.

### Solution to Problem

The specific means for solving the aforementioned problem include the following aspects.

<1> A resin composition for molding, containing: an epoxy resin;
a curing agent containing an active ester compound and a phenol curing agent; and
an inorganic filler containing calcium titanate particles.

<2> The resin composition for molding according to <1>, wherein a content ratio of the calcium titanate particles is 30 volume % to 60 volume % with respect to an inorganic filler as a whole.

<3> The resin composition for molding according to <2>, further containing a stress relaxing agent.

<4> The resin composition for molding according to <3>, wherein the stress relaxing agent contains at least one of indene-styrene-coumarone copolymer, trialkylphosphine oxide, and triarylphosphine oxide.

<5> The resin composition for molding according to any one of <1> to <4>, wherein the phenol curing agent contains aralkyl-type phenol resin and melamine-modified phenol resin.

<6> The resin composition for molding according to any one of <1> to <5>, wherein a content ratio of an inorganic filler as a whole exceeds 55 volume % with respect to a resin composition for molding as a whole.

<7> The resin composition for molding according to any one of <1> to <6>, which is used for a high frequency device.

<8> The resin composition for molding according to any one of <1> to <7>, which is used for sealing an electronic component in a high frequency device.

<9> The resin composition for molding according to any one of <1> to <8>, which is used for an antenna-in-package.

<10> An electronic component device, comprising: a support member;
an electronic component, configured on the support member; and
a cured product of a resin composition for molding according to any one of <1> to <9>, which seals the electronic component.

<11> The electronic component device according to <10>, wherein the electronic component comprises an antenna.

### Effects of Invention

According to the present disclosure, a resin composition for molding capable of molding a cured product with excellent chemical resistance and low dielectric loss tangent, and an electronic component device using the same are provided.

### DESCRIPTION OF EMBODIMENTS

In the present disclosure, the term “step” includes not only steps independent from other steps, but also steps that may not be clearly distinguishable from other steps, as long as the purpose of the step is achieved.

In the present disclosure, a numerical range indicated using “˜” includes the values before and after “˜” as the minimum and maximum values, respectively.

In the numerical ranges described stepwise in the present disclosure, an upper limit or lower limit value described in one numerical range may be replaced with an upper limit or lower limit value of another stepwise described numerical range. Further, in the numerical ranges described in the present disclosure, the upper limit or lower limit value of the numerical range may be replaced with a value shown in the examples.

In the present disclosure, each component may include multiple types of corresponding substances. In the case where multiple types of substances corresponding to each component exist in the composition, the content ratio or content amount of each component means the total content ratio or content amount of the multiple types of substances present in the composition, unless otherwise specified.

In the present disclosure, particles corresponding to each component may include multiple types. In the case where multiple types of particles corresponding to each component exist in the composition, the particle diameter of each component means the value for the mixture of the multiple types of particles present in the composition, unless otherwise specified.

In the present disclosure, “the total content ratio of silica particles and alumina particles” may be reinterpreted as “the content ratio of silica particles” or may be reinterpreted as “the content ratio of alumina particles”.

In the present disclosure, “the total amount of silica particles and alumina particles” may be reinterpreted as “silica particles” or may be reinterpreted as “alumina particles”.

The following describes in detail the embodiments for implementing the present disclosure. However, the present disclosure is not limited to the following embodiments. In the following embodiments, the components (including elements, steps, etc.) are not essential unless specifically stated. The same applies to numerical values and their ranges, which do not limit the present disclosure.

### Resin Composition for Molding

The resin composition for molding of the present disclosure contains an epoxy resin, a curing agent containing an active ester compound and a phenol curing agent; and an inorganic filler containing calcium titanate particles.

As mentioned above, in the resin composition for molding, excellent chemical resistance and low transmission loss are required in the cured product after molding. From the perspective of suppressing transmission loss, it is desirable to achieve a low dielectric loss tangent. In the resin composition for molding of the present disclosure, it is possible to reduce the dielectric loss tangent of the cured product by using calcium titanate particles. Furthermore, by using a combination of an active ester compound and a phenol curing agent as a curing agent for the epoxy resin, it is possible to mold a cured product with excellent chemical resistance.

Furthermore, in the resin composition for molding of the present disclosure, by using calcium titanate particles, it is possible to mold a cured product having a lower dielectric loss tangent compared to the case where barium titanate or the like is used.

The following describes each component constituting the resin composition for molding. The resin composition for molding of the present disclosure contains an epoxy resin, a curing agent, and an inorganic filler, and may include other components as necessary.

### Epoxy Resin

The resin composition for molding of the present disclosure includes an epoxy resin.

The epoxy resin is not particularly limited in type as long as it possesses epoxy groups in its molecule.

The resin composition for molding may include only one type of epoxy resin, or may include two or more types.

Specifically, as the epoxy resin, the following may be mentioned: novolac-type epoxy resins (phenol novolac-type epoxy resin, o-cresol novolac-type epoxy resin, etc.) obtained by epoxidizing novolac resins produced by condensation or co-condensation under acidic catalyst of at least one phenolic compound selected from the group consisting of phenol compounds such as phenol, cresol, xylenol, resorcinol, catechol, bisphenol A, bisphenol F, etc., and naphthol compounds such as α-naphthol, β-naphthol, dihydroxynaphthalene, etc., with aliphatic aldehyde compounds such as formaldehyde, acetaldehyde, propionaldehyde, etc.; triphenylmethane-type epoxy resins obtained by epoxidizing triphenylmethane-type phenol resins produced by condensation or co-condensation under acidic catalyst of the aforementioned phenolic compounds with aromatic aldehyde compounds such as benzaldehyde, salicylaldehyde, etc.; copolymer-type epoxy resins obtained by epoxidizing novolac resins produced by co-condensation under acidic catalyst of the aforementioned phenol compounds and naphthol compounds with aldehyde compounds; diphenylmethane-type epoxy resins which are diglycidyl ethers of bisphenol A, bisphenol F, etc.; biphenyl-type epoxy resins which are diglycidyl ethers of alkyl-substituted or unsubstituted biphenols; stilbene-type epoxy resins which are diglycidyl ethers of stilbene-based phenol compounds; sulfur atom-containing epoxy resins which are diglycidyl ethers of bisphenol S, etc.; epoxy resins which are glycidyl ethers of alcohols such as butanediol, polyethylene glycol, polypropylene glycol, etc.; glycidyl ester-type epoxy resins which are glycidyl esters of polyvalent carboxylic acid compounds such as phthalic acid, isophthalic acid, tetrahydrophthalic acid, etc.; glycidylamine-type epoxy resins in which active hydrogens bonded to nitrogen atoms of aniline, diaminodiphenylmethane, isocyanuric acid, etc. are substituted with glycidyl groups; dicyclopentadiene-type epoxy resins obtained by epoxidizing co-condensation resins of dicyclopentadiene and phenol compounds; alicyclic epoxy resins such as vinylcyclohexene diepoxide, 3,4-epoxycyclohexylmethyl-3,4-epoxycyclohexanecarboxylate, 2-(3,4-epoxy)cyclohexyl-5,5-spiro(3,4-epoxy)cyclohexane-m-dioxane, etc., in which olefin bonds in the molecule are epoxidized; paraxylylene-modified epoxy resins which are glycidyl ethers of paraxylylene-modified phenol resins; metaxylylene-modified epoxy resins which are glycidyl ethers of metaxylylene-modified phenol resins; terpene-modified epoxy resins which are glycidyl ethers of terpene-modified phenol resins; dicyclopentadiene-modified epoxy resins which are glycidyl ethers of dicyclopentadiene-modified phenol resins; cyclopentadiene-modified epoxy resins which are glycidyl ethers of cyclopentadiene-modified phenol resins; polycyclic aromatic ring-modified epoxy resins which are glycidyl ethers of polycyclic aromatic ring-modified phenol resins; naphthalene-type epoxy resins which are glycidyl ethers of naphthalene ring-containing phenol resins; halogenated phenol novolac-type epoxy resins; hydroquinone-type epoxy resins; trimethylolpropane-type epoxy resins; linear aliphatic epoxy resins obtained by oxidizing olefin bonds with peracids such as peracetic acid; aralkyl-type epoxy resins obtained by epoxidizing aralkyl-type phenol resins such as phenol aralkyl resins, naphthol aralkyl resins, etc. Furthermore, epoxidized products of acrylic resins, etc. may also be mentioned as epoxy resins. These epoxy resins may be used alone or in combination of two or more types.

The epoxy resin preferably contains at least one of o-cresol novolac-type epoxy resin, biphenyl aralkyl-type epoxy resin, and biphenyl-type epoxy resin, and more preferably contains o-cresol novolac-type epoxy resin and biphenyl-type epoxy resin, or biphenyl aralkyl-type epoxy resin and biphenyl-type epoxy resin.

The epoxy equivalent (molecular weight/number of epoxy groups) of the epoxy resin is not particularly limited. From the perspective of balancing various characteristics such as moldability, reflow resistance, and electrical reliability, the epoxy equivalent of the epoxy resin is preferably 100 g/eq to 1000 g/eq, and more preferably 150 g/eq to 500 g/eq.

The epoxy equivalent of the epoxy resin is defined as the value measured according to the method conforming to JIS K 7236:2009.

In the case where the epoxy resin is solid, the softening point or melting point of the epoxy resin is not particularly limited. From the perspective of moldability and reflow resistance, the softening point or melting point of the epoxy resin is preferably 40° C. to 180° C., and from the perspective of handling during the preparation of the resin composition for molding, it is more preferably 50° C. to 130° C.

The melting point or softening point of the epoxy resin is defined as the value measured by differential scanning calorimetry (DSC) or by the method conforming to JIS K 7234:1986 (ring and ball method).

The mass ratio of the epoxy resin in the resin composition for molding as a whole is, from the perspective of strength, fluidity, heat resistance, and moldability, preferably 0.5 mass % to 30 mass %, more preferably 2 mass % to 20 mass %, and even more preferably 3.5 mass % to 13 mass %.

### Curing Agent

The resin composition for molding of the present disclosure contains a curing agent. The curing agent contains an active ester compound and a phenol curing agent.

The resin composition for molding may include only one type of active ester compound, or it may include two or more types.

The resin composition for molding may include only one type of phenol curing agent, or it may include two or more types.

### Active Ester Compound

Here, an active ester compound refers to a compound that possesses one or more ester groups in a single molecule that react with epoxy groups, and has a curing effect on epoxy resin.

By using an active ester compound as a curing agent, it is possible to suppress the dielectric loss tangent of the cured product to a low level compared to the case where a phenol curing agent is used alone as a curing agent. The reason for this is presumed to be as follows.

In the reaction between epoxy resin and phenol curing agent, secondary hydroxyl groups are generated. In contrast, in the reaction between epoxy resin and active ester compound, ester groups are formed instead of secondary hydroxyl groups. Since ester groups have lower polarity compared to secondary hydroxyl groups, the resin composition for molding that contains an active ester compound as a curing agent may suppress the dielectric loss tangent of the cured product to a low level compared to the resin composition for molding that contains only curing agents that generate secondary hydroxyl groups.

Further, polar groups in the cured product increase the water absorption of the cured product, and by using an active ester compound as a curing agent, it is possible to suppress the concentration of polar groups in the cured product, thereby inhibiting the water absorption of the cured product. By suppressing the water absorption of the cured product, in other words, by suppressing the content amount of H₂O, which is a polar molecule, it is possible to further suppress the dielectric loss tangent of the cured product to a low level.

The active ester compound is not particularly limited in its type as long as it is a compound that possesses one or more ester groups in the molecule that react with epoxy groups. Examples of active ester compounds include phenol ester compounds, thiophenol ester compounds, N-hydroxyamine ester compounds, and esterified heterocyclic hydroxy compounds.

Examples of active ester compounds include ester compounds obtained from at least one of aliphatic carboxylic acids and aromatic carboxylic acids, and at least one of aliphatic hydroxy compounds and aromatic hydroxy compounds. Ester compounds that contain aliphatic compounds as components of polycondensation tend to have excellent compatibility with epoxy resins due to the presence of aliphatic chains. Ester compounds that contain aromatic compounds as components of polycondensation tend to have excellent heat resistance due to the presence of aromatic rings.

As a specific example of an active ester compound, an aromatic ester obtained by condensation reaction between aromatic carboxylic acid and phenolic hydroxyl group may be mentioned. Among these, an aromatic ester obtained by condensation reaction between aromatic carboxylic acid and phenolic hydroxyl group is preferred, using as raw materials a mixture of: an aromatic carboxylic acid component in which 2 to 4 hydrogen atoms of aromatic rings such as benzene, naphthalene, biphenyl, diphenylpropane, diphenylmethane, diphenyl ether, diphenylsulfonic acid, etc. are substituted with carboxyl groups; a monovalent phenol in which 1 hydrogen atom of the aforementioned aromatic ring is substituted with a hydroxyl group; and a polyvalent phenol in which 2 to 4 hydrogen atoms of the aforementioned aromatic ring are substituted with hydroxyl groups. That is, an aromatic ester having structural units derived from the aforementioned aromatic carboxylic acid component, structural units derived from the aforementioned monovalent phenol, and structural units derived from the aforementioned polyvalent phenol is preferred.

As a specific example of an active ester compound, an active ester resin having a structure obtained by reacting a phenol resin having a molecular structure in which phenol compounds are linked via an aliphatic cyclic hydrocarbon group, an aromatic dicarboxylic acid or its halide, and an aromatic monohydroxy compound, as described in Japanese Patent Application Laid-Open Publication No. 2012-246367, may be mentioned. As such an active ester resin, a compound represented by the following structural formula (1) is preferred.

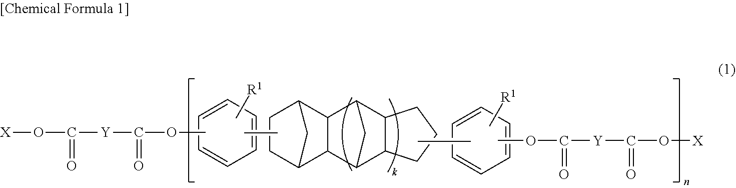

In the structural formula (1), R1 represents a hydrogen atom, an alkyl group having 1 to 4 carbon atoms, or a phenyl group; X represents an unsubstituted benzene ring, an unsubstituted naphthalene ring, a benzene ring or naphthalene ring substituted with an alkyl group having 1 to 4 carbon atoms, or a biphenyl group; Y represents a benzene ring, a naphthalene ring, or a benzene ring or naphthalene ring substituted with an alkyl group having 1 to 4 carbon atoms; k is 0 or 1; and n represents the average number of repetitions and is 0 to 5.

As specific examples of compounds represented by the structural formula (1), exemplary compounds (1-1) to (1-10) shown below may be mentioned. In the structural formulae, t-Bu represents a tert-butyl group.

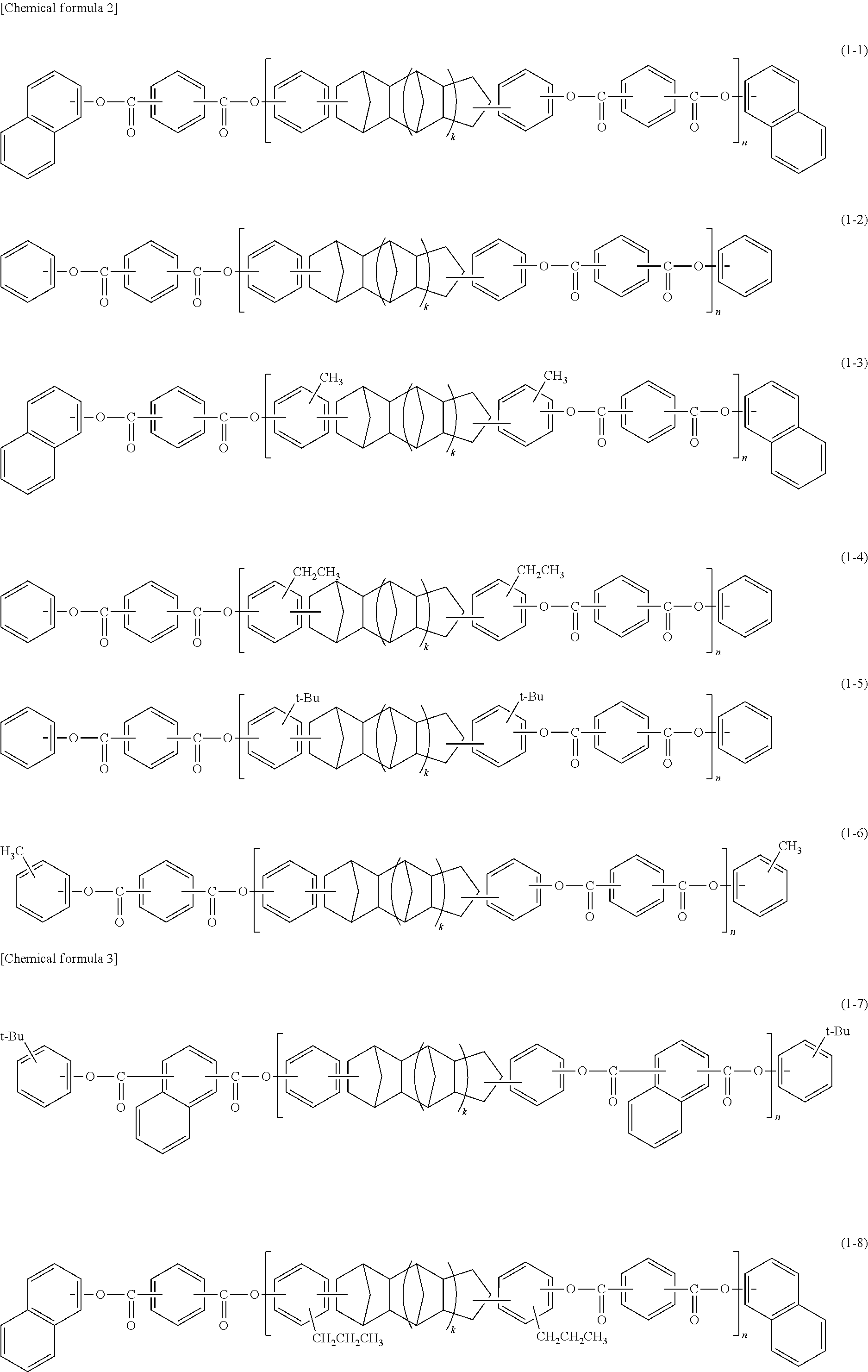

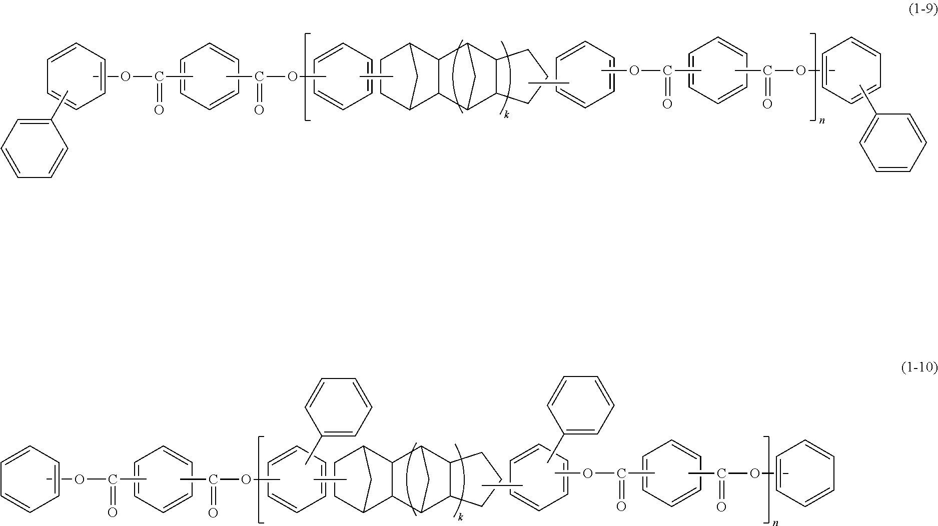

As another specific example of an active ester compound, compounds represented by the following structural formula (2) and compounds represented by the following structural formula (3), as described in Japanese Patent Application Laid-Open Publication No. 2014-114352, may be mentioned.

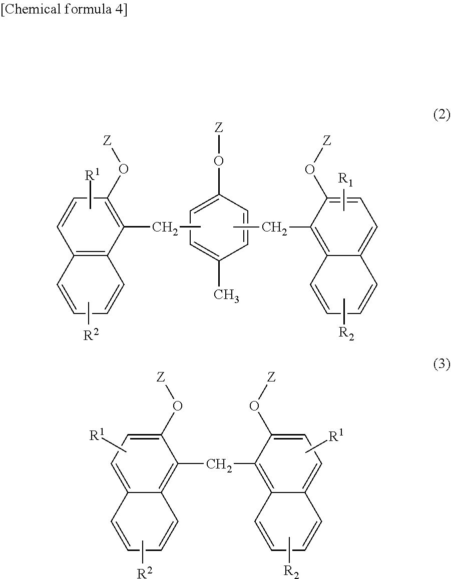

In the structural formula (2), R1 and R2 each independently represent a hydrogen atom, an alkyl group having 1 to 4 carbon atoms, or an alkoxy group having 1 to 4 carbon atoms; Z represents an ester-forming structural moiety (z1) selected from the group consisting of an unsubstituted benzoyl group, an unsubstituted naphthoyl group, a benzoyl group or naphthoyl group substituted with an alkyl group having 1 to 4 carbon atoms, and an acyl group having 2 to 6 carbon atoms, or a hydrogen atom (z2), and at least one of Z is the ester-forming structural moiety (z1).

In the structural formula (3), R1 and R2 each independently represent a hydrogen atom, an alkyl group having 1 to 4 carbon atoms, or an alkoxy group having 1 to 4 carbon atoms; Z represents an ester-forming structural moiety (z1) selected from the group consisting of an unsubstituted benzoyl group, an unsubstituted naphthoyl group, a benzoyl group or naphthoyl group substituted with an alkyl group having 1 to 4 carbon atoms, and an acyl group having 2 to 6 carbon atoms, or a hydrogen atom (z2), and at least one of Z is the ester-forming structural moiety (z1).

As specific examples of compounds represented by the structural formula (2), exemplary compounds (2-1) to (2-6) shown below may be mentioned.

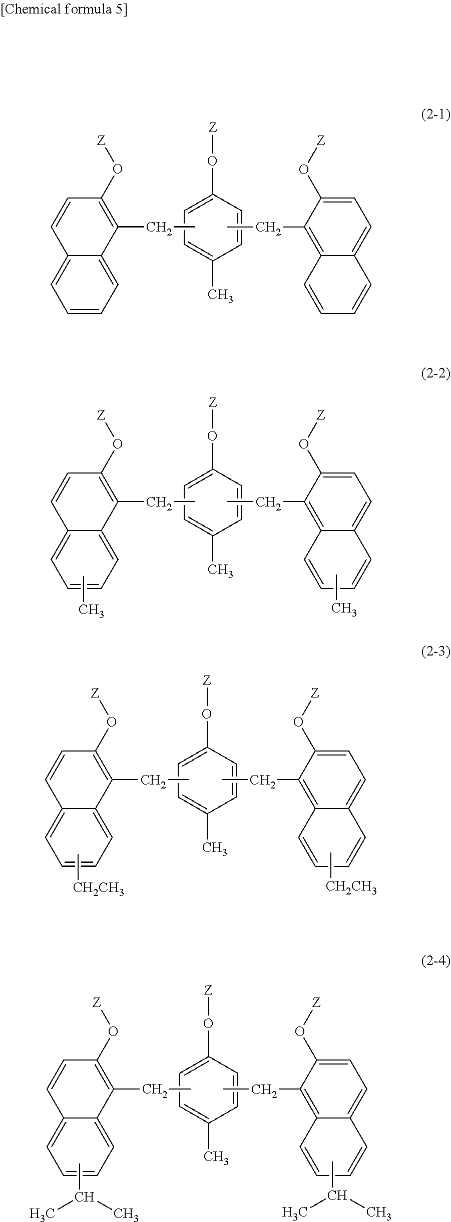

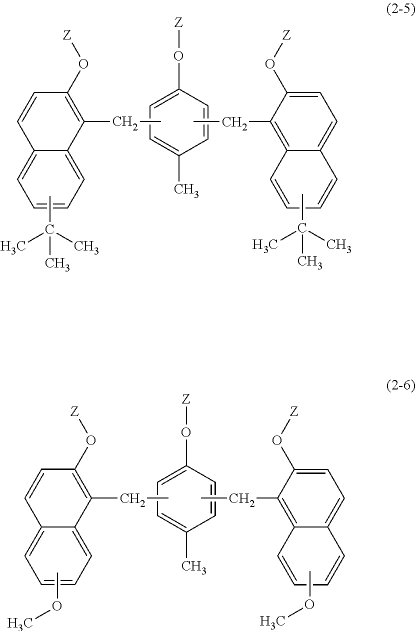

As specific examples of compounds represented by the structural formula (3), exemplary compounds (3-1) to (3-6) shown below may be mentioned.

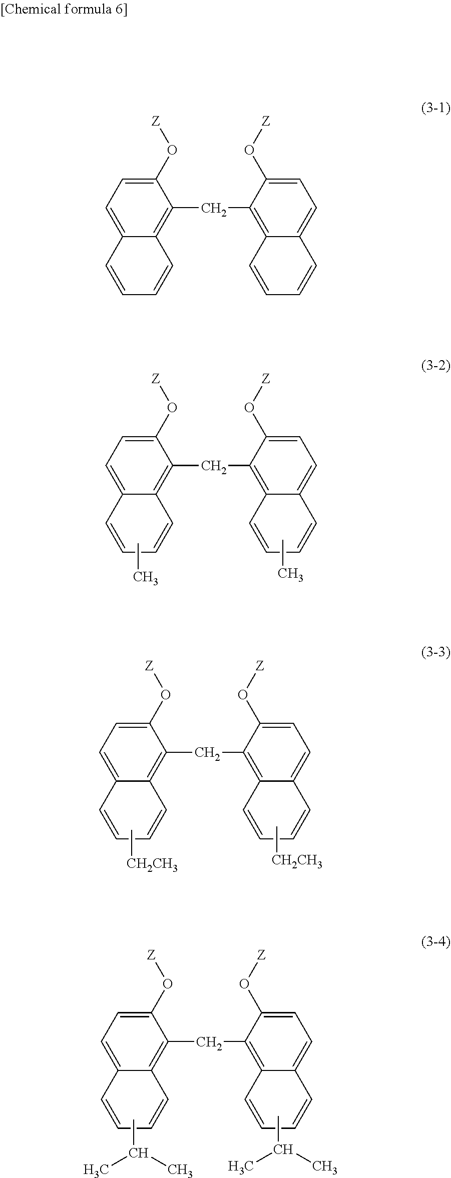

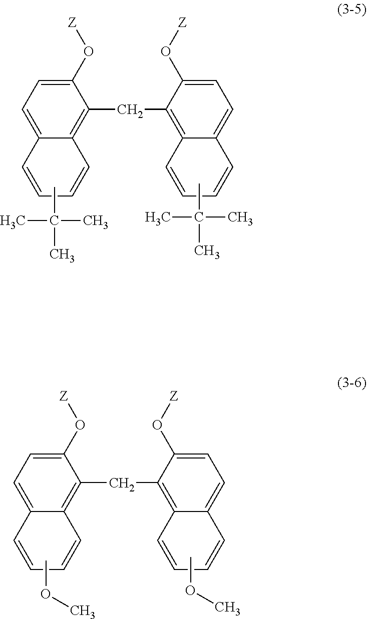

Commercially available products may be used as the active ester compound. Examples of commercially available active ester compounds include: “EXB9451”, “EXB9460”, “EXB9460S”, “HPC-8000-65T” (manufactured by DIC Corporation) as active ester compounds containing a dicyclopentadiene-type diphenol structure; “EXB9416-70BK”, “EXB-8”, “EXB-9425” (manufactured by DIC Corporation) as active ester compounds containing an aromatic structure; “DC808” (manufactured by Mitsubishi Chemical Corporation) as an active ester compound containing an acetylated phenol novolac; “YLH1026” (manufactured by Mitsubishi Chemical Corporation) as an active ester compound containing a benzoylated phenol novolac; and others.

The ester equivalent (molecular weight/number of ester groups) of the active ester compound is not particularly limited. From the perspective of balancing various characteristics such as moldability, reflow resistance, and electrical reliability, 150 g/eq to 400 g/eq is preferable, 170 g/eq to 300 g/eq is more preferable, and 200 g/eq to 250 g/eq is even more preferable.

The ester equivalent of the active ester compound is defined as the value measured according to the method conforming to JIS K 0070:1992.

### Phenol Curing Agent

Specifically, as the phenol curing agent, the following can be mentioned: multivalent phenol compounds such as resorcinol, catechol, bisphenol A, bisphenol F, substituted or unsubstituted biphenols, etc.; novolac-type phenol resins obtained by condensation or co-condensation under acidic catalyst of at least one phenolic compound selected from the group consisting of phenol compounds such as phenol, cresol, xylenol, resorcinol, catechol, bisphenol A, bisphenol F, phenylphenol, aminophenol, and naphthol compounds such as α-naphthol, β-naphthol, dihydroxynaphthalene, with aldehyde compounds such as formaldehyde, acetaldehyde, propionaldehyde; aralkyl-type phenol resins such as phenol aralkyl resins and naphthol aralkyl resins synthesized from the aforementioned phenolic compounds and compounds such as dimethoxy paraxylene, bis(methoxymethyl)biphenyl; paraxylylene-modified phenol resins, metaxylylene-modified phenol resins; melamine-modified phenol resins; terpene-modified phenol resins; dicyclopentadiene-type phenol resins and dicyclopentadiene-type naphthol resins synthesized by copolymerization of the aforementioned phenolic compounds with dicyclopentadiene; cyclopentadiene-modified phenol resins; polycyclic aromatic ring-modified phenol resins; biphenyl-type phenol resins; triphenylmethane-type phenol resins obtained by condensation or co-condensation under acidic catalyst of the aforementioned phenolic compounds with aromatic aldehyde compounds such as benzaldehyde, salicylaldehyde; and phenol resins obtained by copolymerization of two or more of these. These phenol curing agents may be used alone or in combination of two or more types.

Among these, from the perspective of improving adhesion (especially adhesion at high temperatures) to adherends such as electronic components and support members on which the electronic components are mounted in the cured product of the resin composition for molding, it is preferable that the phenol curing agent contains aralkyl-type phenol resin and melamine-modified phenol resin, and it is more preferable that it contains melamine-modified phenol resin.

The reactive group equivalent (for example, hydroxyl equivalent) of the phenol curing agent is not particularly limited. From the perspective of balancing various characteristics such as moldability, reflow resistance, and electrical reliability, it is preferable that the reactive group equivalent of the phenol curing agent is 70 g/eq to 1000 g/eq, and more preferably 80 g/eq to 500 g/eq.

The hydroxyl equivalent of the phenol curing agent is defined as the value measured according to the method conforming to JIS K 0070:1992.

The softening point or melting point of the curing agent is not particularly limited. From the perspective of moldability and reflow resistance, it is preferable that the softening point or melting point of the curing agent is 40° C. to 180° C., and from the perspective of handling during the manufacturing of the resin composition for molding, it is more preferable that it is 50° C. to 130° C.

The melting point or softening point of the curing agent is defined as the value measured in the same manner as the melting point or softening point of the epoxy resin.

The equivalent ratio of the epoxy resin to the curing agent (preferably, the total of the active ester compound and the phenol curing agent), that is, the ratio of the number of functional groups in the curing agent to the number of functional groups in the epoxy resin (number of functional groups in the curing agent/number of functional groups in the epoxy resin), is not particularly limited. From the perspective of suppressing the unreacted portions of each, it is preferable to set it in the range of 0.5 to 2.0, and more preferably in the range of 0.6 to 1.3. From the perspective of moldability and reflow resistance, it is even more preferable to set it in the range of 0.8 to 1.2.

The molar ratio of the ester groups contained in the active ester compound to the reactive groups contained in the phenol curing agent (ester groups/reactive groups in the phenol curing agent) is preferably 9/1 to 1/9, and from the perspective of chemical resistance to alkaline solutions, it is more preferable that it is 8/2 to 2/8, and even more preferable that it is 3/7 to 7/3.

The mass ratio of the active ester compound in the total amount of the active ester compound and the phenol curing agent is preferably 40 mass % to 90 mass %, more preferably 50 mass % to 80 mass %, and even more preferably 55 mass % to 70 mass %, from the perspective of excellent flexural strength after curing the resin composition for molding and suppressing the dielectric loss tangent of the cured product to a low level.

The mass ratio of the phenol curing agent in the total amount of the active ester compound and the phenol curing agent is preferably 10 mass % to 60 mass %, more preferably 20 mass % to 50 mass %, and even more preferably 30 mass % to 45 mass %, from the perspective of excellent flexural strength after curing the resin composition for molding and suppressing the dielectric loss tangent of the cured product to a low level.

In the case where the phenol curing agent contains melamine-modified phenol resin, the content ratio of the melamine-modified phenol resin is preferably 1 mass % to 20 mass %, more preferably 2 mass % to 15 mass %, even more preferably 3 mass % to 10 mass %, and particularly preferably 3 mass % to 8 mass % with respect to the total amount of epoxy resin. By having the content ratio of the melamine-modified phenol resin at 1 mass % or more with respect to the total amount of epoxy resin, there is a tendency for improved adhesion (especially adhesion at high temperatures) to adherends such as electronic components and support members on which such electronic components are mounted in the cured product of the resin composition for molding. By having the content ratio of the melamine-modified phenol resin at 20 mass % or less with respect to the total amount of epoxy resin, there is a tendency to suppress rapid gelation and ensure fluidity, and by having the content ratio of the melamine-modified phenol resin at 8 mass % or less with respect to the total amount of epoxy resin, there is a tendency to suppress the dielectric loss tangent of the cured product.

In the case where the phenol curing agent contains melamine-modified phenol resin and phenol curing agents other than melamine-modified phenol resin (also referred to as other phenol curing agents, preferably aralkyl-type phenol resin), the mass ratio of melamine-modified phenol resin to other phenol curing agents, expressed as melamine-modified phenol resin:other phenol curing agents, may be 1:1 to 1:30, may be 1:2 to 1:20, or may be 1:3 to 1:15.

In the case where the resin composition for molding contains epoxy resin and curing agent, the content ratio of curable resins other than epoxy resin may be less than 5 mass %, may be 4 mass % or less, or may be 3 mass % or less with respect to the resin composition for molding as a whole.

### Inorganic Filler

The resin composition for molding of the present disclosure includes an inorganic filler containing calcium titanate particles.

The inorganic filler may include other fillers other than calcium titanate particles.

### Calcium Titanate Particles

The shape of the calcium titanate particles is not particularly limited, and may include spherical, elliptical, and irregular shapes. Further, the calcium titanate particles may be crushed.

The calcium titanate particles may be surface-treated.

The calcium titanate particles may be a mixture of two or more fillers with different volume average particle diameters.

In the resin composition for molding, the mass ratio of calcium titanate particles to the total of epoxy resin and curing agent (calcium titanate particles/total of epoxy resin and curing agent) is preferably 1 to 25, more preferably 2 to 20, further preferably 3 to 15, and particularly preferably 4 to 12, from the perspective of balance between dielectric loss tangent and fluidity.

The volume average particle diameter of the calcium titanate particles is preferably 0.1 μm to 100 μm, more preferably 0.2 μm to 80 μm, further preferably 0.5 μm to 30 μm, particularly preferably 0.5 μm to 10 μm, and most preferably 0.5 μm to 8 μm.

The volume average particle diameter of the calcium titanate particles may be measured as follows. The resin composition for molding is placed in a crucible and kept at 800° C. for 4 hours to incinerate it. The obtained ash is observed using SEM, separated by shape, and the particle size distribution is determined from the observed images. From this particle size distribution, the volume average particle diameter of the calcium titanate particles may be obtained as the volume average particle diameter (D50). Further, the volume average particle diameter of the calcium titanate particles may be determined by measurement using a laser diffraction/scattering particle size distribution analyzer (for example, LA920 by HORIBA, Ltd.).

The content ratio of calcium titanate particles is preferably 30 volume % to 60 volume %, more preferably 35 volume % to 55 volume %, and further preferably 40 volume % to 50 volume % with respect to the inorganic filler as a whole, from the perspective of balance between relative permittivity and dielectric loss tangent.

### At Least One of Silica Particles and Alumina Particles

The inorganic filler preferably includes at least one of silica particles and alumina particles. The inorganic filler may include only one of silica particles and alumina particles, or may include both. Silica particles and alumina particles may each be used independently alone or in combination of two or more types. Silica particles and alumina particles may each be a mixture of two or more types of fillers with different volume average particle diameters.

The silica particles are not particularly limited, and include fused silica, crystalline silica, glass, etc. The shape of the silica particles is not particularly limited, and includes spherical, elliptical, irregular shapes, etc. The silica particles may be crushed.

The silica particles may be surface-treated.

The shape of the alumina particles is not particularly limited, and includes spherical, elliptical, irregular shapes, etc. The alumina particles may be crushed.

The alumina particles may be surface-treated.

From the perspective of relative permittivity and thermal conductivity, it is preferable that the inorganic filler contains alumina particles.

In the case where the inorganic filler contains at least one of silica particles and alumina particles, the total content ratio of silica particles and alumina particles is preferably 40 volume % to 70 volume %, more preferably 45 volume % to 65 volume %, and even more preferably 50 volume % to 60 volume % with respect to the inorganic filler as a whole, from the perspective of low dielectric loss tangent.

The content ratio (volume %) of silica particles, the content ratio (volume %) of alumina particles, and the content ratio (volume %) of calcium titanate particles with respect to the inorganic filler as a whole may be determined by the following method.

A thin slice sample of the cured product of the resin composition for molding is imaged using a scanning electron microscope (SEM). In the SEM image, an arbitrary area S is identified, and the total area A of the inorganic filler included in the area S is determined. Next, using SEM-EDX (Energy Dispersive X-ray Spectroscopy), the elements of the inorganic filler are identified to determine the total area B of specific particles such as silica particles, alumina particles, calcium titanate particles, etc. included in the total area A of the inorganic filler. The value obtained by dividing the total area B of the specific particles by the total area A of the inorganic filler is converted to a percentage (%), and this value is used as the content ratio (volume %) of the specific particles with respect to the inorganic filler as a whole.

The area S is set to be sufficiently large compared to the size of the inorganic filler. For example, the size is set to be large enough to contain more than 100 inorganic filler particles. The area S may be the sum of multiple cross-sectional areas.

In the resin composition for molding, the mass ratio of the total of silica particles and alumina particles to the total of epoxy resin and curing agent (total of silica particles and alumina particles/total of epoxy resin and curing agent) is preferably 1 to 25, more preferably 2 to 20, even more preferably 3 to 15, and particularly preferably 4 to 12, from the perspective of balance between dielectric loss tangent and fluidity.

The volume average particle diameter of silica particles and the volume average particle diameter of alumina particles are not particularly limited. The volume average particle diameter of silica particles and the volume average particle diameter of alumina particles are preferably, independently of each other, 0.2 μm to 100 μm, and more preferably 0.5 μm to 50 μm. In the case where the aforementioned volume average particle diameter is 0.2 μm or more, there is a tendency for the increase in viscosity of the resin composition for molding to be more suppressed. In the case where the aforementioned volume average particle diameter is 100 μm or less, there is a tendency for the filling properties of the resin composition for molding to be more improved.

For the volume average particle diameter of the silica particles and the volume average particle diameter of the alumina particles, the resin composition for molding is placed in a crucible and kept at 800° C. for 4 hours to incinerate it. The obtained ash is observed using SEM, separated by shape, and the particle size distribution is determined from the observed images. From this particle size distribution, the volume average particle diameter of silica particles and the volume average particle diameter of alumina particles may be obtained as the volume average particle diameter (D50). Further, the volume average particle diameter of silica particles and the volume average particle diameter of alumina particles may be determined by measurement using a laser diffraction/scattering particle size distribution analyzer (for example, LA920 by HORIBA, Ltd.).

The volume average particle diameter of silica particles and the volume average particle diameter of alumina particles may be, independently of each other, 3 μm or more or 5 μm or more from the perspective of the viscosity of the resin composition for molding, or may be 10 μm or more or 20 μm or more from the perspective of the fluidity of the resin composition for molding.

In the case where the inorganic filler contains at least one of silica particles and alumina particles, the total content ratio of silica particles, alumina particles, and calcium titanate particles may be 90 volume % or more, may be 95 volume % or more, or may be 100 volume % with respect to the inorganic filler as a whole.

### Other Fillers

The inorganic filler may include other fillers other than silica particles, alumina particles, or calcium titanate particles.

The shape of the other fillers is not particularly limited, and includes spherical, elliptical, and irregular shapes. Further, the other fillers may be crushed.

The other fillers may be surface-treated.

The other fillers may be used alone or in combination of two or more types. The other fillers may be a mixture of two or more fillers with different volume average particle diameters.

The type of other fillers is not particularly limited. Specific materials for the other fillers include inorganic materials such as calcium carbonate, zirconium silicate, calcium silicate, silicon nitride, aluminum nitride, boron nitride, beryllia, zirconia, zircon, forsterite, steatite, spinel, mullite, titania, talc, clay, and mica.

Inorganic fillers with flame-retardant effects may be used as other fillers. Inorganic fillers with flame-retardant effects include aluminum hydroxide, magnesium hydroxide, composite metal hydroxides such as magnesium and zinc composite hydroxide, and zinc borate.

The content ratio of other fillers may be 10 volume % or less, 5 mass % or less, or 0 volume % or less with respect to the inorganic filler as a whole.

The other fillers may include titanium compound particles other than calcium titanate particles. Titanium compound particles other than calcium titanate particles include strontium titanate particles, barium titanate particles, potassium titanate particles, magnesium titanate particles, lead titanate particles, aluminum titanate particles, lithium titanate, and titanium oxide particles.

However, from the perspective of suppressing the dielectric loss tangent of the cured product to a low level, the content ratio of barium titanate particles is preferably less than 1 volume %, more preferably less than 0.5 volume %, and even more preferably less than 0.1 volume % with respect to the inorganic filler as a whole. That is, the inorganic filler preferably does not contain barium titanate particles or contains barium titanate particles at the aforementioned content ratio.

Further, the total content ratio of titanium compound particles other than calcium titanate particles may be less than 1 volume %, less than 0.5 volume %, or less than 0.1 volume % with respect to the inorganic filler as a whole. That is, the inorganic filler may not contain titanium compound particles other than calcium titanate particles, or may contain titanium compound particles other than calcium titanate particles at the aforementioned content ratio.

The preferable range for the volume average particle diameter of other fillers is similar to the preferable ranges for the volume average particle diameter of silica particles and the volume average particle diameter of alumina particles.

### Content Ratio and Characteristics of Inorganic Filler as a Whole

The content ratio of the inorganic filler as a whole included in the resin composition for molding is preferably more than 50 volume %, more preferably more than 55 volume %, even more preferably more than 55 volume % and 90 volume % or less, and particularly preferably 60 volume % to 80 volume % with respect to the resin composition for molding as a whole, from the perspective of controlling the fluidity and strength of the cured product of the resin composition for molding.

The content ratio (volume %) of the inorganic filler in the resin composition for molding may be obtained by the following method.

A thin slice sample of the cured product of the resin composition for molding is imaged using a scanning electron microscope (SEM). In the SEM image, an arbitrary area S is identified, and the total area A of the inorganic filler included in the area S is determined. The value obtained by dividing the total area A of the inorganic filler by the area S is converted to a percentage (%), and this value is considered as the content ratio (volume %) of the inorganic filler in the resin composition for molding.

The area S is set to be sufficiently large compared to the size of the inorganic filler. For example, the size is set to be large enough to contain more than 100 inorganic filler particles. The area S may be the sum of multiple cross-sectional areas.

The inorganic filler may develop a bias in its distribution ratio in the gravity direction during the curing of the resin composition for molding. In such a case, when imaging with SEM, the gravity direction as a whole of the cured product is imaged, and the area S that includes the gravity direction as a whole of the cured product is identified.

### Curing Accelerator

The resin composition for molding of the present disclosure may include a curing accelerator as needed. The type of curing accelerator is not particularly limited and may be selected according to the type of epoxy resin, desired characteristics of the resin composition for molding, and other factors.

As curing accelerators, the following may be mentioned: cyclic amidine compounds such as 1,5-diazabicyclo[4.3.0]non-5-ene (DBN), 1,8-diazabicyclo[5.4.0]undec-7-ene (DBU) and other diazabicycloalkenes, 2-methylimidazole, 2-phenylimidazole, 2-phenyl-4-methylimidazole, 2-ethyl-4-methylimidazole, 2-heptadecylimidazole; derivatives of the aforementioned cyclic amidine compounds; phenol novolac salts of the aforementioned cyclic amidine compounds or their derivatives; compounds having intramolecular polarization formed by adding compounds with π-bonds such as quinone compounds like maleic anhydride, 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, phenyl-1,4-benzoquinone, and diazophenylmethane to these compounds; cyclic amidinium compounds such as tetraphenylborate salt of DBU, tetraphenylborate salt of DBN, 2-ethyl-4-methylimidazole, N-methylmorpholine; tertiary amine compounds such as pyridine, triethylamine, triethylenediamine, benzyldimethylamine, triethanolamine, dimethylaminoethanol, tris(dimethylaminomethyl)phenol; derivatives of the aforementioned tertiary amine compounds; ammonium salt compounds such as tetra-n-butylammonium acetate, tetra-n-butylammonium phosphate, tetraethylammonium acetate, tetra-n-hexylammonium benzoate, tetrapropylammonium hydroxide; organic phosphines such as primary phosphines like ethylphosphine and phenylphosphine, secondary phosphines like dimethylphosphine and diphenylphosphine, tertiary phosphines like triphenylphosphine, diphenyl(p-tolyl)phosphine, tris(alkylphenyl)phosphine, tris(alkoxyphenyl)phosphine, tris(alkyl⋅alkoxyphenyl)phosphine, tris(dialkylphenyl)phosphine, tris(trialkylphenyl)phosphine, tris(tetraalkylphenyl)phosphine, tris(dialkoxyphenyl)phosphine, tris(trialkoxyphenyl)phosphine, tris(tetraalkoxyphenyl)phosphine, trialkylphosphine, dialkylalylphosphine, alkyldiarylphosphine, trinaphthylphosphine, tris(benzyl)phosphine; phosphine compounds such as complexes of the aforementioned organic phosphines with organic boron compounds; compounds having intramolecular polarization formed by adding compounds with π-bonds such as quinone compounds like maleic anhydride, 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, phenyl-1,4-benzoquinone, anthraquinone, and diazophenylmethane to the aforementioned organic phosphines or phosphine compounds; compounds having intramolecular polarization obtained through a dehydrohalogenation process after reacting the aforementioned organic phosphines or phosphine compounds with halogenated phenol compounds such as 4-bromophenol, 3-bromophenol, 2-bromophenol, 4-chlorophenol, 3-chlorophenol, 2-chlorophenol, 4-iodophenol, 3-iodophenol, 2-iodophenol, 4-bromo-2-methylphenol, 4-bromo-3-methylphenol, 4-bromo-2,6-dimethylphenol, 4-bromo-3,5-dimethylphenol, 4-bromo-2,6-di-tert-butylphenol, 4-chloro-1-naphthol, 1-bromo-2-naphthol, 6-bromo-2-naphthol, 4-bromo-4′-hydroxybiphenyl; tetrasubstituted phosphonium compounds such as tetraphenylphosphonium, tetraphenylborate salts of tetrasubstituted phosphonium like tetraphenylphosphonium tetra-p-tolylborate, salts of tetrasubstituted phosphonium with phenol compounds; salts of tetraalkylphosphonium with partial hydrolysates of aromatic carboxylic acid anhydrides; phosphobetaine compounds; adducts of phosphonium compounds with silane compounds; and others.

The curing accelerator may be used alone or in combination of two or more types.

Among these, it is preferable that the curing accelerator contain an organic phosphine. As the curing accelerator containing an organic phosphine, the aforementioned organic phosphine, phosphine compounds such as complexes of the aforementioned organic phosphine with organic boron compounds, compounds having intramolecular polarization formed by adding compounds with π-bonds to the aforementioned organic phosphine or the aforementioned phosphine compounds may be mentioned.

Among these, particularly preferable curing accelerators include trialkylphosphine, adducts of trialkylphosphine and quinone compounds, triphenylphosphine, adducts of triphenylphosphine and quinone compounds, adducts of tributylphosphine and quinone compounds, and adducts of tri-p-tolylphosphine and quinone compounds.

In the case where the resin composition for molding includes a curing accelerator, its amount is preferably 0.1 to 30 parts by mass, more preferably 1 to 15 parts by mass, with respect to 100 parts by mass of the total of epoxy resin and curing agent. When the amount of the curing accelerator is 0.1 parts by mass or more with respect to 100 parts by mass of the total of epoxy resin and curing agent, there is a tendency for good curing in a short time. When the amount of the curing accelerator is 30 parts by mass or less with respect to 100 parts by mass of the total of epoxy resin and curing agent, there is a tendency to obtain a good molded product without the curing speed being too fast.

### Stress Relaxing Agent

The resin composition for molding of the present disclosure may include a stress relaxing agent. By including a stress relaxing agent, it is possible to further reduce the occurrence of package warpage deformation and package cracks. As the stress relaxing agent, known stress relaxing agents (flexibilizers) generally used may be mentioned. Specifically, thermoplastic elastomers such as silicone-based, styrene-based, olefin-based, urethane-based, polyester-based, polyether-based, polyamide-based, polybutadiene-based, etc., indene-styrene-coumarone copolymer, etc., trialkylphosphine oxide, triarylphosphine oxide such as triphenylphosphine oxide, organic phosphorus compounds such as phosphoric acid esters, rubber particles such as NR (natural rubber), NBR (acrylonitrile-butadiene rubber), acrylic rubber, urethane rubber, silicone powder, etc., rubber particles having a core-shell structure such as methyl methacrylate-butadiene-styrene copolymer (MBS), methyl methacrylate-silicone copolymer, methyl methacrylate-butyl acrylate copolymer, etc. may be mentioned. The stress relaxing agent may be used alone or in combination of two or more types.

As silicone-based stress relaxing agents, those having epoxy groups, those having amino groups, and those modified with polyether may be mentioned, and silicone compounds such as silicone compounds having epoxy groups and polyether-based silicone compounds are more preferable.

From the perspective of dielectric loss tangent, it is preferable that the stress relaxing agent includes at least one of indene-styrene-coumarone copolymer, trialkylphosphine oxide, and triarylphosphine oxide. The stress relaxing agent may include at least one of indene-styrene-coumarone copolymer and triphenylphosphine oxide.

In the case where the resin composition for molding includes a stress relaxing agent, its amount is, for example, preferably 1 to 30 parts by mass, more preferably 2 to 20 parts by mass, with respect to 100 parts by mass of the total of epoxy resin and curing agent.

In the case where the stress relaxing agent includes at least one of indene-styrene-coumarone copolymer, trialkylphosphine oxide, and triarylphosphine oxide (preferably, in the case where it includes at least one of indene-styrene-coumarone copolymer and triphenylphosphine oxide), its amount is, for example, preferably 1 to 30 parts by mass, more preferably 2 to 20 parts by mass, with respect to 100 parts by mass of the total of epoxy resin and curing agent.

The content amount of the silicone-based stress relaxing agent may be, for example, 2 parts by mass or less, or 1 part by mass or less, with respect to 100 parts by mass of the total of epoxy resin and curing agent. The resin composition for molding may not include a silicone-based stress relaxing agent. The lower limit value of the content amount of the silicone-based stress relaxing agent is not particularly limited, and may be 0 parts by mass or 0.1 parts by mass.

From the perspective of dielectric loss tangent, the content ratio of the silicone-based stress relaxing agent is preferably 20 mass % or less, more preferably 10 mass % or less, further preferably 7 mass % or less, particularly preferably 5 mass % or less, and most preferably 0.5 mass % or less, with respect to the resin composition for molding as a whole. The lower limit value of the content ratio of the silicone-based stress relaxing agent is not particularly limited, and may be 0 mass % or 0.1 mass %.

### Various Additives

The resin composition for molding of the present disclosure may include various additives such as coupling agents, ion exchangers, release agents, flame retardants, and colorants, as exemplified below, in addition to the aforementioned components. The resin composition for molding of the present disclosure may also include various additives well-known in the technical field as needed, other than the additives exemplified below.

### Coupling Agent

The resin composition for molding of the present disclosure may include a coupling agent. From the perspective of improving adhesion between the epoxy resin and curing agent and the inorganic filler, it is preferable that the resin composition for molding includes a coupling agent. As the coupling agent, known coupling agents such as silane-based compounds including epoxysilane, mercaptosilane, aminosilane, alkylsilane, ureidosilane, vinylsilane, disilazane, etc., titanium-based compounds, aluminum chelate-based compounds, and aluminum/zirconium-based compounds may be mentioned.

In the case where the resin composition for molding includes a coupling agent, the amount of the coupling agent is preferably 0.05 parts by mass to 5 parts by mass, more preferably 0.1 parts by mass to 2.5 parts by mass, with respect to 100 parts by mass of the inorganic filler. When the amount of the coupling agent is 0.05 parts by mass or more with respect to 100 parts by mass of the inorganic filler, there is a tendency for improved adhesion with the frame. When the amount of the coupling agent is 5 parts by mass or less with respect to 100 parts by mass of the inorganic filler, there is a tendency for improved moldability of the package.

### Ion Exchanger

The resin composition for molding of the present disclosure may include an ion exchanger. From the perspective of improving moisture resistance and high-temperature storage characteristics of electronic component devices equipped with electronic components to be sealed, it is preferable that the resin composition for molding includes an ion exchanger. The ion exchanger is not particularly limited, and conventionally known ones may be used. Specifically, hydrotalcite compounds, and hydrated hydroxides of at least one element selected from the group consisting of magnesium, aluminum, titanium, zirconium, and bismuth may be mentioned. The ion exchanger may be used alone or in combination of two or more types. Among these, hydrotalcite represented by the following general formula (A) is preferable.

Mg_{(1-X)}Al_{X}(OH)₂(CO₃)_{X/2}·mH₂O (A)

(0<X≤0.5, and m is a positive number)

In the case where the resin composition for molding includes an ion exchanger, its content is not particularly limited as long as it is sufficient to capture ions such as halogen ions. For example, the content of the ion exchanger is preferably 0.1 parts by mass to 30 parts by mass, more preferably 1 part by mass to 10 parts by mass, with respect to 100 parts by mass of the total of epoxy resin and curing agent.

### Release Agent

The resin composition for molding of the present disclosure may include a release agent from the perspective of obtaining good release properties from the mold during molding. The release agent is not particularly limited, and conventionally known ones may be used. Specifically, carnauba wax, montan acid, higher fatty acids such as stearic acid, metal salts of higher fatty acids, ester-based waxes such as montan acid ester, polyolefin-based waxes such as oxidized polyethylene and non-oxidized polyethylene may be mentioned. The release agent may be used alone or in combination of two or more types.

In the case where the resin composition for molding includes a release agent, its amount is preferably 0.01 parts by mass to 10 parts by mass, more preferably 0.1 parts by mass to 5 parts by mass, with respect to 100 parts by mass of the total of epoxy resin and curing agent. When the amount of release agent is 0.01 parts by mass or more with respect to 100 parts by mass of the total of epoxy resin and curing agent, there is a tendency to obtain sufficient release properties. When it is 10 parts by mass or less, there is a tendency to obtain better adhesion.

### Flame Retardant

The resin composition for molding of the present disclosure may include a flame retardant. The flame retardant is not particularly limited, and conventionally known ones may be used. Specifically, organic or inorganic compounds containing halogen atoms, antimony atoms, nitrogen atoms or phosphorus atoms, metal hydroxides, etc. may be mentioned. The flame retardant may be used alone or in combination of two or more types.

In the case where the resin composition for molding includes a flame retardant, its amount is not particularly limited as long as it is sufficient to obtain the desired flame retardant effect. For example, the amount of flame retardant is preferably 1 part by mass to 30 parts by mass, more preferably 2 parts by mass to 20 parts by mass, with respect to 100 parts by mass of the total of epoxy resin and curing agent.

### Colorant

The resin composition for molding of the present disclosure may include a colorant. As the colorant, known colorants such as carbon black, organic dyes, organic pigments, titanium oxide, red lead, bengala may be mentioned. The content amount of the colorant may be appropriately selected according to the purpose, etc. The colorant may be used alone or in combination of two or more types.

### Method for Preparing Resin Composition for Molding

The method for preparing the resin composition for molding is not particularly limited. As a general technique, a method may be mentioned in which components in predetermined formulation amounts are sufficiently mixed by a mixer or the like, then melt-kneaded by a mixing roll. extruder, or the like, cooled, and pulverized. More specifically, for example, a method may be mentioned in which predetermined amounts of the aforementioned components are stirred and mixed, kneaded in a kneader, roll, extruder, or the like preheated to 70° C. to 140° C., cooled, and pulverized.

The resin composition for molding of the present disclosure is preferably solid under normal temperature and pressure conditions (for example, at 25° C., under atmospheric pressure). In the case where the resin composition for molding is solid, its shape is not particularly limited, and powder, granular, tablet forms, etc. may be mentioned. In the case where the resin composition for molding is in tablet form, it is preferable from the perspective of handling that the dimensions and mass are such that they match the molding conditions of the package.

### Characteristics of Resin Composition for Molding

The relative permittivity at 10 GHz of a cured product obtained by compression molding the resin composition for molding of the present disclosure under conditions of a mold temperature of 175° C., a molding pressure of 6.9 MPa, and a curing time of 600 seconds may be, for example, 5 to 30. The relative permittivity at 10 GHz of the aforementioned cured product is preferably 6 to 25, more preferably 7 to 20, and even more preferably 8 to 17 from the perspective of miniaturization of electronic components such as antennas.

The measurement of the above relative permittivity is performed using a relative permittivity measuring device (for example, product name “Network Analyzer N5227A”, manufactured by Agilent Technologies) at a temperature of 25±3° C.

The dielectric loss tangent at 10 GHz of a cured product obtained by compression molding the resin composition for molding of the present disclosure under conditions of a mold temperature of 175° C., a molding pressure of 6.9 MPa, and a curing time of 600 seconds may be, for example. 0.015 or less. The dielectric loss tangent at 10 GHz of the aforementioned cured product is preferably 0.010 or less, more preferably 0.007 or less, and even more preferably 0.005 or less from the perspective of reducing transmission loss. The lower limit value of the dielectric loss tangent at 10 GHz of the aforementioned cured product is not particularly limited, and for example, 0.001 may be mentioned.

The measurement of the above dielectric loss tangent is performed using a dielectric constant measuring device (for example, product name “Network Analyzer N5227A”, manufactured by Agilent Technologies) at a temperature of 25±3° C.

### Applications of Resin Composition for Molding

The resin composition for molding of the present disclosure may be applied, for example, to the manufacture of electronic component devices, particularly high-frequency devices, as described later. The resin composition for molding of the present disclosure may also be used for sealing electronic components in high-frequency devices.

In particular, in recent years, with the spread of the fifth-generation mobile communication system (5G), semiconductor packages (PKG) used in electronic component devices are becoming more advanced in functionality and smaller in size. Along with the miniaturization and increased functionality of PKGs, the development of Antenna in Package (AiP), which is a PKG with antenna functionality, is also progressing. In AiPs, to accommodate the increase in the number of channels due to the diversification of information, the radio waves used for communication are becoming higher in frequency, and sealing materials are required to have a low dielectric loss tangent.

The resin composition for molding of the present disclosure, as mentioned above, yields a cured product with a low dielectric loss tangent. Thus, it is particularly suitable for Antenna in Package (AiP) applications in high-frequency devices, where an antenna configured on a support member is sealed with the resin composition for molding.

In electronic component devices including antennas, such as Antenna in Package, heat generation occurs due to power supply when an amplifier for power supply is provided on the opposite side of the antenna. From the perspective of improving heat dissipation, the resin composition for molding used in the manufacture of electronic component devices preferably includes alumina particles as an inorganic filler.

### Electronic Component Device

The electronic component device of the present disclosure includes a support member, an electronic component configured on the support member, and a cured product of the aforementioned resin composition for molding that seals the electronic component.

Examples of electronic component devices include those (e.g., high-frequency devices) in which an electronic component area obtained by mounting electronic components (active elements such as semiconductor chips, transistors, diodes, and thyristors; passive elements such as capacitors, resistors, and coils; antennas, etc.) on support members such as lead frames, wired tape carriers, wiring boards, glass, silicon wafers, and organic substrates, is sealed with the resin composition for molding.

The type of the aforementioned support member is not particularly limited, and support members generally used in the manufacture of electronic component devices may be used.

The aforementioned electronic component may include an antenna, or may include both an antenna and elements other than the antenna. The aforementioned antenna is not limited as long as it serves the role of an antenna, and it may be an antenna element or a wiring.

Further, in the electronic component device of the present disclosure, if necessary, other electronic components may be configured on the opposite side of the surface where the aforementioned electronic component is configured on the support member. The other electronic components may be sealed with the aforementioned resin composition for molding, may be sealed with another resin composition, or may not be sealed.

### Manufacturing Method of Electronic Component Device

The manufacturing method of the electronic component device of the present disclosure includes a step of configuring an electronic component on a support member, and a step of sealing the electronic component with the aforementioned resin composition for molding.

The method for implementing each of the aforementioned steps is not particularly limited, and may be carried out using general techniques. Further, the types of support members and electronic components used in the manufacture of the electronic component device are not particularly limited, and support members and electronic components generally used in the manufacture of electronic component devices may be used.

Methods for sealing the electronic component using the aforementioned resin composition for molding include low-pressure transfer molding, injection molding, and compression molding. Among these, low-pressure transfer molding is common.

### EXAMPLE

The following examples specifically describe the aforementioned embodiments, but the scope of the aforementioned embodiments is not limited to these examples.

### Preparation of Resin Composition for Molding

The components shown below were mixed in the formulation ratios (parts by mass) shown in Table 1 and Table 2 to prepare resin compositions for molding of the examples and comparative examples. These resin compositions for molding were solid under normal temperature and pressure conditions.

It is noted that in Tables 1 and 2, blank cells indicate that the component is not included.

Further, Table 1 and Table 2 also show the content ratio of inorganic filler (indicated as “Content ratio (volume %)” in the tables) relative to the resin composition for molding as a whole.

Further, CTO/Total inorganic filler in the tables represents the content ratio (volume %) of calcium titanate particles relative to the inorganic filler as a whole.
Epoxy resin 1: o-cresol novolac type epoxy resin, epoxy equivalent 200 g/eq
Epoxy resin 2: Biphenyl aralkyl type epoxy resin, epoxy equivalent 275 g/eq
Epoxy resin 3: Biphenyl-type epoxy resin, epoxy equivalent 196 g/eq
Curing agent 1: Active ester compound, product name “EXB-8”, manufactured by DIC Corporation
Curing agent 2: Phenol curing agent, aralkyl-type phenol resin, hydroxyl equivalent 170 g/eq
Curing agent 3: Melamine-modified phenol resin, reactive group equivalent 120 g/eq
Curing accelerator: Adduct of trialkylphosphine and 1,4-benzoquinone
Coupling agent: N-phenyl-3-aminopropyltrimethoxysilane (product name “KBM-573”, manufactured by Shin-Etsu Chemical Co., Ltd.)
Release agent: Montan acid ester wax (product name “HW-E”, manufactured by Clariant Catalysts (Japan) K.K.)
Coloring agent: Carbon black
Stress relaxing agent 1: Indene-styrene-coumarone copolymer
Stress relaxing agent 2: Triarylphosphine oxide
Inorganic filler 1: Calcium titanate particles, volume average particle diameter: 0.2 μm, shape: irregular (CT-110)
Inorganic filler 2: Alumina particles, volume average particle diameter: 5.7 μm, shape: spherical
Inorganic filler 3: Calcium titanate particles, volume average particle diameter: 4.0 μm, shape: irregular

It is noted that the volume average particle diameter of each of the aforementioned inorganic fillers is the value obtained by the following measurement.

Specifically, first, the inorganic filler was added to a dispersion medium (water) in a range of 0.01 mass % to 0.1 mass %, and dispersed for 5 minutes using a bath-type ultrasonic cleaner.

5 ml of the obtained dispersion was injected into a cell, and the particle size distribution was measured at 25° C. using a laser diffraction/scattering particle size distribution analyzer (LA920, HORIBA, Ltd.).

The particle diameter at the cumulative value of 50% (volume basis) in the obtained particle size distribution was defined as the volume average particle diameter.

### Measurement of Gel Time

The gel time (GT) of the thermosetting resin composition was measured using a Curastometer from JSR Trading Co., Ltd. The measurement was conducted at 180° C. using a Curastometer from JSR Trading Co., Ltd. for 3 g of the thermosetting resin composition, and the time until the rise of the torque curve was defined as the gel time (seconds). The results are shown in Table 1 and Table 2.

### Evaluation of Spiral Flow (SF)

Using a mold for measuring spiral flow in accordance with EMMI-1-66, the thermosetting resin composition was molded by a transfer molding machine under the conditions of a mold temperature of 180° C. a molding pressure of 6.9 MPa, and a curing time of 120 seconds to determine the flow distance (cm). The results are shown in Table 1 and Table 2.

### Adhesion Test

### Adhesion Strength to Copper (Cu)

The resin composition for molding was molded on a copper plate using a transfer molding machine under the conditions of a mold temperature of 180° C., a molding pressure of 6.9 MPa, and a curing time of 90 seconds, to form a shape with a bottom diameter of 4 mm, a top diameter of 3 mm, and a height of 4 mm. Subsequently, post-curing was performed on the molded product under the conditions of 175° C. for 5 hours. After that, using a bond tester (Series 4000, manufactured by Nordson Advanced Technology Co., Ltd.), the shear adhesion strength (MPa) was determined at room temperature (25° C.), or while maintaining the copper plate temperature at 260° C., with a shear rate of 50 μm/s. The evaluation criteria for adhesion are shown below. If the evaluation is A or B, the adhesion is considered good.

### Evaluation Criteria for Adhesion (25° C.)

A: Shear adhesion strength is 10.5 MPa or higher
B: Shear adhesion strength is 9.5 MPa or higher and less than 10.5 MPa
C: Shear adhesion strength is less than 9.5 MPa

### Evaluation Criteria for Adhesion (260° C.)

A: Shear adhesion strength is 1.0 MPa or higher
B: Shear adhesion strength is 0.6 MPa or higher and less than 1.0 MPa
C: Shear adhesion strength is less than 0.6 MPa

The results are shown in Table 1 and Table 2.

### Chemical Resistance Test

The resin composition for molding was loaded into a transfer molding machine and molded under the conditions of a mold temperature of 180° C., molding pressure of 6.9 MPa, and curing time of 90 seconds, followed by post-curing at 175° C. for 6 hours to obtain a rod-shaped cured product (5 mm×5 mm×20 mm). Using the rod-shaped cured product as a test piece, it was immersed in a mixed solution of DMSO (dimethyl sulfoxide)/TMAH (tetramethylammonium hydroxide, 25% AQ.)=92/8 (mass ratio) at 80° C. for 1 hour. Using the mass before immersion as a reference, the retention rate (mass %) was calculated from the mass of the test piece after 1 hour according to the following formula. The evaluation criteria for chemical resistance are shown below. If the evaluation is A or B, the chemical resistance is considered good.

Retention rate (mass %)=(Mass after immersion (g)/Mass before immersion (g))×100

### Evaluation Criteria for Chemical Resistance

A: Retention rate is 80 mass % or more
B: Retention rate is 30 mass % to 80 mass %
C: Retention rate is greater than 0 mass % and 30 mass % or less
D: Retention rate is 0 mass %

The results are shown in Table 1 and Table 2.

### Measurement of Relative Permittivity and Dielectric Loss Tangent

The resin composition for molding was loaded into a transfer molding machine and molded under the conditions of a mold temperature of 180° C., molding pressure of 6.9 MPa, and curing time of 90 seconds, followed by post-curing at 175° C. for 6 hours to produce a rectangular parallelepiped test piece measuring 90 mm×0.6 mm×1.0 mm.

The relative permittivity (Dk) and dielectric loss tangent (Df) of this test piece were measured at a frequency of 10 GHz using a cavity resonator (Kanto Electronics Application & Development Inc.) and a network analyzer (Keysight Technologies, model name “PNAN 5227A”) by the cavity resonance method in an environment at 25±3° C. The results are shown in Table 1 and Table 2.

TABLE 1

| | | | Example 1 | Example 2 | Example 3 | Example 4 | Example 5 |
|---|---|---|---|---|---|---|---|
| Epoxy resin | | Epoxy resin 1 | | | | 70 | |
| | | Epoxy resin 2 | 70 | 70 | 70 | | 70 |
| | | Epoxy resin 3 | 30 | 30 | 30 | 30 | 30 |
| Curing agent | | Curing agent 1 | 52 | 52 | 52 | 64 | 77.6 |
| | | Curing agent 2 | 28 | 23 | 28 | 35 | 8.03 |
| | | Curing agent 3 | 3 | 6 | 3 | 3 | |
| Curing accelerator | | Curing accelerator | 3 | 3 | 3 | 3 | 3 |
| Coupling agent | | Coupling agent | 5 | 5 | 5 | 5 | 5 |
| Release agent | | Release agent | 1 | 1 | 1 | 1 | 1 |
| Coloring agent | | Coloring agent | 5 | 5 | 5 | 5 | 5 |
| Stress relaxing agent | | Stress relaxing agent 1 | | | 10 | | |
| | | Stress relaxing agent 2 | | | 5 | | |
| Total content ratio of inorganic fillers (volume %) | | | 60 | 60 | 73 | 73 | 60 |
| Inorganic filler | | Inorganic filler 1 | 105 | 104 | 113 | 115 | 106 |
| | | Inorganic filler 2 | 497 | 492 | 537 | 545 | 505 |
| | | Inorganic filler 3 | 417 | 413 | 452 | 456 | 423 |
| Total | | | 1216 | 1204 | 1314 | 1332 | 1234 |
| CTO/total amount of inorganic filler (volume ratio) | | | 51.2 | 51.2 | 51.3 | 51.2 | 51.2 |
| Mass ratio of curing agent 3 to epoxy resin | | | 3 | 6 | 3 | 3 | 0 |
| Ester group/phenolic hydroxyl group (molar ratio) | | | 6/4 | 6/4 | 6/4 | 6/4 | 9/1 |
| Evaluation item | | Unit | | | | | |
| Gel time | s | s | 70 | 75 | 70 | 60 | 55 |
| SF | cm | cm | 150 | 150 | 120 | 150 | 160 |

| | | | | | | |
|---|---|---|---|---|---|---|
| Adhesion (25° C.) | — | A | A | A | A | B |
| Adhesion (260° C.) | — | A | A | A | A | C |
| Chemical resistance | — | A | A | A | A | B |
| Dk@10 GHz | — | 16.7 | 16.7 | 16.2 | 16.4 | 16.7 |
| Df@10 GHz | — | 0.008 | 0.008 | 0.007 | 0.008 | 0.006 |

| | | | | Comparative | Comparative |
|---|---|---|---|---|---|
| | | | Example 6 | Example 1 | Example 2 |
| Epoxy resin | | Epoxy resin 1 | | | |
| | | Epoxy resin 2 | 70 | 70 | 70 |
| | | Epoxy resin 3 | 30 | 30 | 30 |
| Curing agent | | Curing agent 1 | 52 | 86 | |
| | | Curing agent 2 | 32.4 | | 81.9 |
| | | Curing agent 3 | | | |
| Curing accelerator | | Curing accelerator | 3 | 3 | 3 |
| Coupling agent | | Coupling agent | 5 | 5 | 5 |
| Release agent | | Release agent | 1 | 1 | 1 |
| Coloring agent | | Coloring agent | 5 | 5 | 5 |
| Stress relaxing agent | | Stress relaxing agent 1 | | | |
| | | Stress relaxing agent 2 | | | |
| Total content ratio of inorganic fillers (volume %) | | | 60 | 60 | 60 |
| Inorganic filler | | Inorganic filler 1 | 106 | 107 | 104 |
| | | Inorganic filler 2 | 502 | 506 | 496 |
| | | Inorganic filler 3 | 421 | 424 | 416 |
| Total | | | 1228 | 1237 | 1212 |
| CTO/total amount of inorganic filler (volume ratio) | | | 51.2 | 51.2 | 51.2 |
| Mass ratio of curing agent 3 to epoxy resin | | | 0 | 0 | 0 |
| Ester group/phenolic hydroxyl group (molar ratio) | | | 6/4 | 10/0 | 10/0 |
| Evaluation item | | Unit | | | |
| Gel time | s | s | 50 | 65 | 45 |
| SF | cm | cm | 150 | 200 | 200 |

| | | | | |
|---|---|---|---|---|
| Adhesion (25° C.) | — | A | B | C |
| Adhesion (260° C.) | — | C | B | C |
| Chemical resistance | — | A | D | A |
| Dk@10 GHz | — | 15.8 | 15.8 | 16.0 |
| Df@10 GHz | — | 0.009 | 0.006 | 0.012 |

TABLE 2

| | | | Example 7 | Example 8 | Example 9 | Example 10 | Example 11 | Example 12 |
|---|---|---|---|---|---|---|---|---|
| Epoxy resin | | Epoxy resin 1 | | | | | 50 | 30 |
| | | Epoxy resin 2 | 70 | 70 | 50 | 30 | | |
| | | Epoxy resin 3 | 30 | 30 | 50 | 70 | 50 | 70 |
| Curing agent | | Curing agent 1 | 52 | 52 | 55.5 | 59.4 | 64 | 64.5 |
| | | Curing agent 2 | 28 | 16 | 30.2 | 32.8 | 35.7 | 35.9 |
| | | Curing agent 3 | 3 | 10 | 3 | 3 | 3 | 3 |
| Curing accelerator | | Curing accelerator | 3 | 3 | 3 | 3 | 3 | 3 |
| Coupling agent | | Coupling agent | 5 | 5 | 5 | 5 | 5 | 5 |
| Release agent | | Release agent | 1 | 1 | 1 | 1 | 1 | 1 |
| Coloring agent | | Coloring agent | 5 | 5 | 5 | 5 | 5 | 5 |
| Stress relaxing agent | | Stress relaxing agent1 | 10 | | | | | |
| | | Stress relaxing agent2 | 5 | | | | | |
| Total content ratio of inorganic fillers (volume %) | | | 60 | 60 | 60 | 60 | 60 | 60 |
| Inorganic filler | | Inorganic filler 1 | 110 | 100 | 106 | 109 | 113 | 114 |
| | | Inorganic filler 2 | 525 | 477 | 504 | 519 | 538 | 539 |
| | | Inorganic filler 3 | 440 | 399 | 422 | 435 | 450 | 452 |
| Total | | | 1287 | 1168 | 1235 | 1272 | 1318 | 1322 |
| CTO/total amount of inorganic filler (volume ratio) | | | 51.2 | 51.1 | 51.2 | 51.2 | 51.1 | 51.2 |
| Mass ratio of curing agent 3 to epoxy resin | | | 3 | 10 | 3 | 3 | 3 | 3 |
| Ester group/phenolic hydroxyl group (molar ratio) | | | 6/4 | 6/4 | 6/4 | 6/4 | 6/4 | 6/4 |
| Evaluation item | | Unit | | | | | | |
| Gel time | s | s | 75 | 80 | 75 | 75 | 70 | 75 |
| SF | cm | cm | 140 | 135 | 160 | 170 | 165 | 170 |

| | | | | | | | |
|---|---|---|---|---|---|---|---|
| Adhesion (25° C.) | — | A | A | A | A | A | A |
| Adhesion (260° C.) | — | A | A | A | A | A | A |
| Chemical resistance | — | A | A | A | A | A | A |
| Dk@10 GHz | — | 16.4 | 16.5 | 16.0 | 15.9 | 16.3 | 15.8 |
| Df@10 GHz | — | 0.008 | 0.009 | 0.008 | 0.007 | 0.008 | 0.007 |

As shown in Table 1 and Table 2, the resin composition for molding in the examples was able to achieve both excellent chemical resistance and low dielectric loss tangent.

Furthermore, the resin compositions for molding in Examples 1 to 4 and 7 to 12, which used curing agent 3, also showed good evaluation results for adhesion (25° C.) and adhesion (260° C.).

The disclosure of Japanese Patent Application No. 2022-094677 is incorporated in its entirety into this specification by reference.

All literature, patent applications, and technical standards described in this specification are incorporated into this specification by reference to the same extent as if each individual literature, patent application, and technical standard were specifically and individually indicated to be incorporated by reference.

1. A resin composition for molding, containing:
an epoxy resin;
a curing agent containing an active ester compound and a phenol curing agent; and
an inorganic filler containing calcium titanate particles.

2. The resin composition for molding according to claim 1, wherein a content ratio of the calcium titanate particles is 30 volume % to 60 volume % with respect to an inorganic filler as a whole.

3. The resin composition for molding according to claim 1, further containing a stress relaxing agent.

4. The resin composition for molding according to claim 3, wherein the stress relaxing agent contains at least one of indene-styrene-coumarone copolymer, trialkylphosphine oxide, and triarylphosphine oxide.

5. The resin composition for molding according to claim 1, wherein the phenol curing agent contains aralkyl-type phenol resin and melamine-modified phenol resin.

6. The resin composition for molding according to claim 1, wherein a content ratio of an inorganic filler as a whole exceeds 55 volume % with respect to a resin composition for molding as a whole.

7. The resin composition for molding according to claim 1, which is used for a high frequency device.

8. The resin composition for molding according to claim 7, which is used for sealing an electronic component in a high frequency device.

9. The resin composition for molding according to claim 7, which is used for an antenna-in-package.

10. An electronic component device, comprising:
a support member;
an electronic component, configured on the support member; and
a cured product of a resin composition for molding according to claim 1, which seals the electronic component.

11. The electronic component device according to claim 10, wherein the electronic component comprises an antenna.
